(19) United States
(12) Patent Application Publication
(10) Pub. No.: US 2020/0127043 A1
(43) Pub. Date: Apr. 23, 2020

(54) METHOD OF PRODUCING SEMICONDUCTOR EPITAXIAL WAFER, SEMICONDUCTOR EPITAXIAL WAFER, AND METHOD OF PRODUCING SOLID-STATE IMAGE SENSING DEVICE

(71) Applicant: SUMCO Corporation, Tokyo (JP)

(72) Inventors: Takeshi Kadono, Minato-ku (JP); Kazunari Kurita, Minato-ku (JP)

(73) Assignee: SUMCO Corporation, Tokyo (JP)

(21) Appl. No.: 16/717,722

(22) Filed: Dec. 17, 2019

Related U.S. Application Data
(63) Continuation of application No. 14/442,355, filed on May 12, 2015, now abandoned.

(30) Foreign Application Priority Data
Nov. 13, 2012 (JP) 2012-249731

(51) Int. Cl. H01L 27/146; H01L 29/167; H01L 21/324; H01L 21/322; H01L 21/265; H01L 21/02; C30B 29/06; C30B 25/18; C23C 14/48

(52) U.S. Cl. CPC H01L 27/14687; C23C 14/48; H01L 21/324; H01L 21/3221; H01L 21/26566; H01L 21/26513; H01L 21/26506; H01L 21/02658; H01L 21/02381; H01L 21/2658; C30B 29/06; C30B 25/186; H01L 21/02439; H01L 21/02576; H01L 21/02532; H01L 21/02579; H01L 27/14689; H01L 29/167

(57) ABSTRACT

The present invention provides a method of producing a semiconductor epitaxial wafer, which can suppress metal contamination by achieving higher gettering capability.

The method of producing a semiconductor epitaxial wafer includes a first step of irradiating a surface portion 10A of a semiconductor wafer 10 with cluster ions 16 thereby forming a modifying layer 18 formed from carbon and a dopant element contained as a solid solution that are constituent elements of the cluster ions 16, in the surface portion 10A of the semiconductor wafer; and a second step of forming an epitaxial layer 20 on the modifying layer 18 of the semiconductor wafer, the epitaxial layer 20 having a dopant element concentration lower than the peak concentration of the dopant element in the modifying layer 18.

### TECHNICAL FIELD

The present invention relates to a method of producing a semiconductor epitaxial wafer, a semiconductor epitaxial wafer, and a method of producing a solid-state image sensing device. The present invention relates, in particular, to a method of producing a semiconductor epitaxial wafer, which can suppress metal contamination by achieving higher gettering capability.

### BACKGROUND

Metal contamination is one of the factors that deteriorate the characteristics of a semiconductor device. For example, for a back-illuminated solid-state image sensing device, metal mixed into a semiconductor epitaxial wafer to be a substrate of the device causes increased dark current in the solid-state image sensing device, and results in the formation of defects referred to as white spot defects. In recent years, back-illuminated solid-state image sensing devices have been widely used in digital video cameras and mobile phones such as smartphones, since they can directly receive light from the outside, and take sharper images or motion pictures even in dark places and the like due to the fact that a wiring layer and the like thereof are disposed at a lower layer than a sensor section. Therefore, it is desirable to reduce white spot defects as much as possible.

Mixing of metal into a wafer mainly occurs in a process of producing a semiconductor epitaxial wafer and a process of producing a solid-state image sensing device (device fabrication process). Metal contamination in the former process of producing a semiconductor epitaxial wafer may be due to heavy metal particles from components of an epitaxial growth furnace, or heavy metal particles caused by the metal corrosion of piping materials of the furnace due to chlorine-based gas used during epitaxial growth in the furnace. In recent years, such metal contaminations have been reduced to some extent by replacing components of epitaxial growth furnaces with highly corrosion resistant materials, but not to a sufficient extent. On the other hand, in the latter process of producing a solid-state image sensing device, heavy metal contamination of semiconductor substrates would occur in process steps such as ion implantation, diffusion, and oxidizing heat treatment in the producing process.

For those reasons, conventionally, heavy metal contamination of semiconductor epitaxial wafers has been prevented by forming, in the semiconductor wafer, a gettering sink for trapping the metal, or by using a substrate having high ability to trap the metal (gettering capability), such as a high boron concentration substrate.

In general, a gettering sink is formed in a semiconductor wafer by an intrinsic gettering (IG) method in which an oxygen precipitate (commonly called a silicon oxide precipitate, and also called a bulk micro defect (BMD)) or dislocation that are crystal defects is formed within the semiconductor wafer, or an extrinsic gettering (EG) method in which the gettering sink is formed on the rear surface of the semiconductor wafer.

Here, a technique of forming a gettering site in a semiconductor wafer by monomer ion (single ion) implantation can be given as a technique for gettering heavy metal. JP H06-338507 A (PTL 1) discloses a production method, by which carbon ions are implanted through a surface of a silicon wafer to form a carbon ion implanted region, and an epitaxial silicon layer is formed on the surface thereby obtaining an epitaxial silicon wafer. In that technique, the carbon ion implanted region serves as a gettering site.

Further, JP 2007-036250 A (PTL 2) describes a method of fabricating an epitaxial semiconductor substrate, including the steps of: forming a non-carrier dopant layer (e.g., carbon) and a carrier dopant layer (e.g., boron (B) as a Group XIII element and arsenic (As) as a Group XV element) including the non-carrier dopant layer therein in a semiconductor substrate; and forming an epitaxial layer on an upper surface of the substrate.

Furthermore, JP 2010-177233 (PTL 3) describes a method of producing an epitaxial wafer, in which a silicon single crystal substrate is ion-implanted with at least one of boron, carbon, aluminum, arsenic, and antimony at a dose in the range of 5×10¹⁴ atoms/cm² to 1×10¹⁶ atoms/cm², and after cleaning performed without performing recovery heat treatment on the silicon single crystal substrate, an epitaxial layer is formed at a temperature of 1100° C. or more using a single-wafer processing epitaxial apparatus.

### CITATION LIST

### Patent Literature

PTL 1: JP H06-338507 A
PTL 2: JP 2007-036250 A
PTL 3: JP 2010-177233 A

### SUMMARY

In all of the techniques described in PTLs 1 to 3, one or more monomer ions (single ions) are implanted into a semiconductor wafer before the formation of an epitaxial layer. However, according to studies made by the inventors of the present invention, it was found that the gettering capability is insufficient in semiconductor epitaxial wafers subjected to monomer-ion implantation, and stronger gettering capability is desired.

In view of the above problems, an object of the present invention is to provide a semiconductor epitaxial wafer having metal contamination reduced by achieving higher gettering capability, a method of producing the semiconductor epitaxial wafer, and a method of producing a solid-state image sensing device by which a solid-state image sensing device is formed from the semiconductor epitaxial wafer.

According to studies made by the inventors of the present invention, it was found that irradiating a semiconductor wafer with cluster ions is advantageous in the following points as compared with the case of implanting monomer ions. Specifically, even if irradiation with cluster ions is performed at the same acceleration voltage as the case of monomer ion implantation, the cluster ions collide with the semiconductor wafer with a lower energy per one atom of carbon constituting cluster ions and/or of a dopant element than in the case of implanting carbon and a dopant element in the form of monomer ions. Accordingly, the peak position of the concentration profile of carbon and the dopant element used for the irradiation can be made to lie steeply in the vicinity of the surface of the semiconductor wafer, and since the irradiation can be performed with a plurality of atoms at once, the concentration can be high. Thus, the gettering capability was found to be improved.

Based on the above findings, the inventors completed the present invention.

A method of producing a semiconductor epitaxial wafer, according to the present invention comprises a first step of irradiating a surface portion of a semiconductor wafer with cluster ions thereby forming a modifying layer formed from carbon and a dopant element contained as a solid solution that are constituent elements of the cluster ions, in the surface of the semiconductor wafer; and a second step of forming an epitaxial layer on the modifying layer of the semiconductor wafer, the epitaxial layer having a dopant element concentration lower than the peak concentration of the dopant element in the modifying layer.

Here, the cluster ions are preferably formed by ionizing a compound containing both the carbon and the dopant element.

Further, the dopant element may be one or more elements selected from the group consisting of boron, phosphorus, arsenic, and antimony.

Here, the semiconductor wafer may be a silicon wafer.

Further, the semiconductor wafer may be an epitaxial silicon wafer in which an epitaxial silicon layer is formed on a surface of a silicon wafer. In this case, the modifying layer is formed in the surface portion of the epitaxial silicon layer in the first step.

A semiconductor epitaxial wafer, according to the preset invention comprises: a semiconductor wafer; a modifying layer formed from carbon and a dopant element contained as a solid solution in the semiconductor wafer, the modifying layer being formed in a surface portion of the semiconductor wafer; and an epitaxial layer on the modifying layer. The half width of the concentration profile of the carbon in the modifying layer and the half width of the concentration profile of the dopant element therein are 100 nm or less, and the concentration of the dopant element in the epitaxial layer is lower than the peak concentration of the dopant element in the modifying layer.

Here, the dopant element may be one or more elements selected from the group consisting of boron, phosphorus, arsenic, and antimony.

Here, the semiconductor wafer may be a silicon wafer.

Further, the semiconductor wafer may be an epitaxial silicon wafer in which an epitaxial silicon layer is formed on a surface of a silicon wafer. In this case, the modifying layer is located in the surface portion of the epitaxial silicon layer.

Further, the peak of the concentration profile of either the carbon or the dopant element in the modifying layer preferably lies at a depth within 150 nm from the surface of the semiconductor wafer. The peak concentration of the concentration profile of the carbon in the modifying layer is preferably 1×10¹⁵ atoms/cm³ or more, and it is also preferable that the peak concentration of the concentration profile of the dopant element in the modifying layer is 1×10¹⁵ atoms/cm³ or more.

In a method of producing a solid-state image sensing device according to the present invention, a solid-state image sensing device is formed on the epitaxial layer located in the surface portion of the epitaxial wafer fabricated by any one of the above production methods or of any one of the above epitaxial wafers.

### Advantageous Effect of Invention

According to the present invention, a semiconductor wafer is irradiated with cluster ions thereby forming a modifying layer constituted from a solid solution of carbon and a dopant element that are constituent elements of the cluster ions, on the semiconductor wafer, which allows the modifying layer to have higher gettering capability; accordingly, a semiconductor epitaxial wafer which can suppress metal contamination can be obtained and a high quality solid-state image sensing device can be formed from the semiconductor epitaxial wafer.

### BRIEF DESCRIPTION OF THE DRAWINGS

FIGS. 1(A) to 1(D) are schematic cross-sectional views illustrating a method of producing a semiconductor epitaxial wafer 100 according to a first embodiment of the present invention.

FIGS. 2(A) to 2(E) are schematic cross-sectional views illustrating a method of producing a semiconductor epitaxial wafer 200 according to another embodiment of the present invention.

FIG. 3(A) is a schematic view illustrating the irradiation mechanism for irradiation with cluster ions. FIG. 3(B) is a schematic view illustrating the implantation mechanism for implanting a monomer ion.

FIGS. 4(A) and 4(B) show the concentration profile of a dopant element, obtained by SIMS in Reference Examples 1 and 2, in which irradiation with cluster ions was performed. FIG. 4(A) illustrates Reference Example 1, whereas FIG. 4(B) illustrates Reference Example 2.

FIGS. 5(A) and 5(B) show the concentration profile of a dopant element, obtained by SIMS in Reference Examples 3 and 4, in which implantation with monomer ions was performed. FIG. 5(A) illustrates Reference Example 3, whereas FIG. 5(B) illustrates Reference Example 4.

FIGS. 6(A) and 6(B) show the concentration profile of a dopant element, obtained by SIMS in Examples 1 and 2, in which irradiation with cluster ions was performed. FIG. 6(A) illustrates Example 1, whereas FIG. 6(B) illustrates Example 2.

FIGS. 7(A) to 7(C) show the concentration profile of a dopant element, obtained by SIMS in Comparative Examples 1 to 3, in which implantation with monomer ions was performed. FIG. 7(A) illustrates Comparative Example 1, FIG. 7(B) illustrates Comparative Example 2, and FIG. 7(C) illustrates Comparative Example 3.

### DETAILED DESCRIPTION

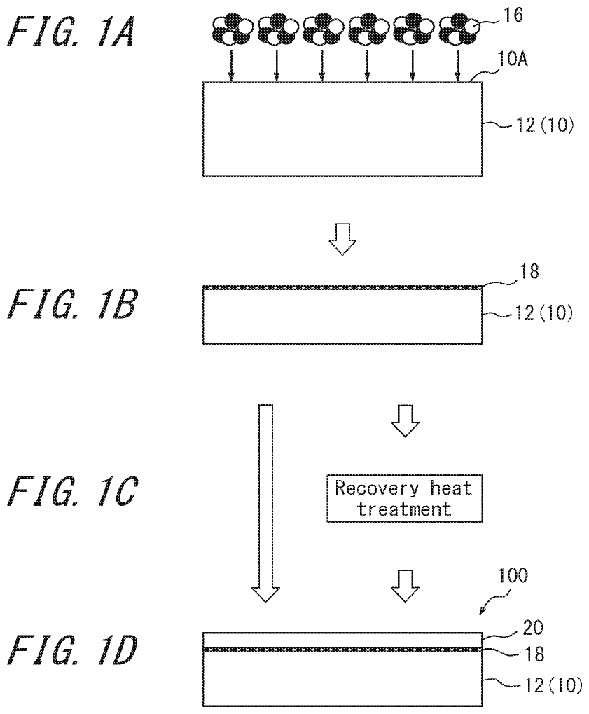

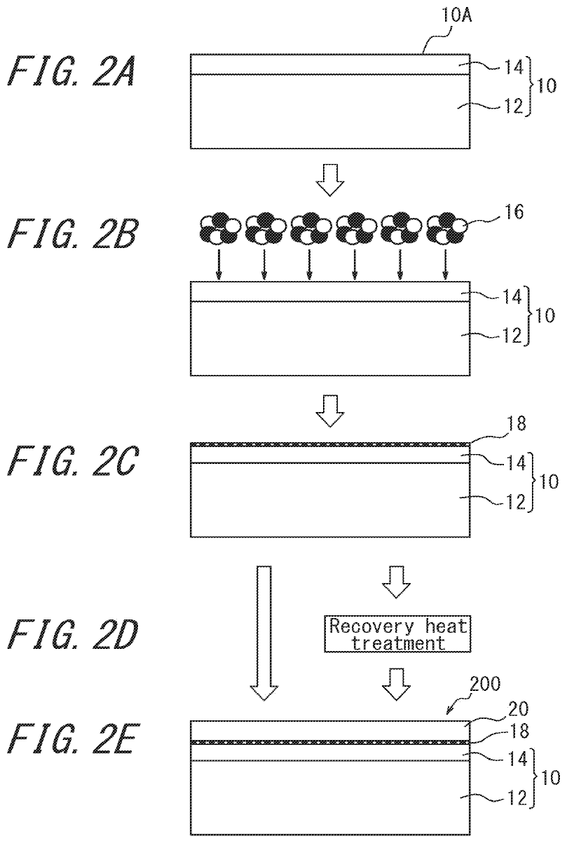

Embodiments of the present invention will now be described in detail with reference to the drawings. In principle, the same components are denoted by the same reference numeral, and the description will not be repeated. Further, in FIGS. 1(A) to 1(D) and FIGS. 2(A) to 2(E), a first epitaxial layer 14 and a second epitaxial layer 20 are exaggerated with respect to a semiconductor wafer 10 in thickness for the sake of explanation, so the thickness ratio does not conform to the actual ratio.

### (Method of Producing Semiconductor Epitaxial Wafer)

FIG. 1 shows a method of producing a semiconductor epitaxial wafer 100 according to a first embodiment of the present invention. First, a first step is performed in which a surface portion 10A of a semiconductor wafer 10 is irradiated with cluster ions 16 thereby forming a modifying layer 18 constituted from a solid solution of carbon and a dopant element that are constituent elements of the cluster ions 16, in the surface portion 10A of the semiconductor wafer 10 (FIGS. 1(A) and 1(B)). Next, a second step is performed in which the semiconductor wafer 10 is cleaned by a known cleaning method such as SC-1 cleaning or HF cleaning, and an epitaxial layer 20 having a dopant element concentration lower than the concentration of the dopant element in the modifying layer 18 is then formed on the modifying layer 18 of the semiconductor wafer 10 (FIG. 1(D)). FIG. 1(D) is a schematic cross-sectional view of the semiconductor epitaxial wafer 100 obtained by this production method.

Examples of the semiconductor wafer 10 include, for example, a bulk single crystal wafer including silicon or a compound semiconductor (GaAs, GaN, or SiC) with no epitaxial layer on the surface thereof. In the case of producing a back-illuminated solid-state image sensing device, a bulk single crystal silicon wafer is typically used. Further, the semiconductor wafer 10 may be prepared by growing a single crystal silicon ingot by the Czochralski process (CZ process) or floating zone melting process (FZ process) and slicing it with a wire saw or the like. Further, carbon and/or nitrogen may be added thereto to achieve higher gettering capability. Furthermore, the semiconductor wafer 10 may be made n-type or p-type by adding certain impurities. The first embodiment shown in FIGS. 1(A) to 1(D) is an example of using a bulk semiconductor wafer 12 with no epitaxial layer on its surface, as the semiconductor wafer 10.

Alternatively, an epitaxial semiconductor wafer in which a semiconductor epitaxial layer (first epitaxial layer) 14 is formed on a surface of the bulk semiconductor wafer 12 as shown in FIG. 2(A), can be given as an example of the semiconductor wafer 10. An example is an epitaxial silicon wafer in which a silicon epitaxial layer is formed on a surface of a bulk single crystal silicon wafer. The silicon epitaxial layer can be formed by chemical vapor deposition (CVD) process under typical conditions. The first epitaxial layer 14 preferably has a thickness in the range of 0.1 μm to 10 μm, more preferably in the range of 0.2 μm to 5 μm.

For example, in a method of producing a semiconductor epitaxial wafer 200 according to a second embodiment of the present invention, as shown in FIGS. 2(A) to 2(E), a first step (FIGS. 2(A) to 2(C)) of irradiating a surface portion 10A of a semiconductor wafer 10, in which a first epitaxial layer 14 is formed on a surface (at least one side) of a bulk semiconductor wafer 12, with cluster ions 16 to form a modifying layer 18 constituted from a solid solution of carbon and a dopant element that are constituent elements of the cluster ions 16, in the surface portion 10A of the semiconductor wafer (the surface portion of the first epitaxial layer 14 in this embodiment) is first performed. Further, a second step is performed in which the semiconductor wafer 10 is cleaned by a given method, and an epitaxial layer 20 having a dopant element concentration lower than the concentration of the dopant element in the modifying layer 18 is then formed on the modifying layer 18 of the semiconductor wafer 10 (FIG. 2(E)). FIG. 2(E) is a schematic cross-sectional view of the semiconductor epitaxial wafer 200 obtained by this production method.

Here, a characteristic step of the present invention is the step of irradiating the surface portion 10A of the semiconductor wafer with cluster ions 16 thereby forming the modifying layer 18 constituted from a solid solution of from a solid solution of carbon and a dopant element that are constituent elements of the cluster ions 16 as shown in FIG. 1(A) and FIG. 2(B).

In one embodiment, in the first step, irradiation is performed individually with cluster ions formed by ionizing a compound containing carbon and with different cluster ions formed by ionizing a compound containing a dopant element so that the modifying layer 18 formed from carbon and the dopant element contained as a solid solution can be formed. In this case, the irradiation energy and the dose of the cluster ions can easily be controlled, which is preferable. As described below, the peak position of the concentration profile of each element can also be relatively easily controlled.

Further, in another embodiment, in the first step, irradiation is performed with the cluster ions 16 formed by ionizing a compound containing by ionizing a compound containing both the carbon and the dopant element so that the modifying layer 18 formed from carbon and the dopant element contained as a solid solution can be formed. Irradiation with such a compound in the form of cluster ions allows both carbon and a dopant element to form a solid solution localized in the vicinity of the surface of the silicon wafer, so that the production efficiency can also be improved.

The technical meaning of employing the above first step will be described with the operation and effect. The modifying layer 18 formed as a result of irradiation with the cluster ions 16 is a region where the constituent elements (carbon and the dopant element) of the cluster ions 16 are localized as a solid solution at crystal interstitial positions or substitution positions in the crystal lattice of the surface portion of the semiconductor wafer, which region functions as a gettering site. The reason may be as follows. After irradiation in the form of cluster ions, elements such as carbon and the dopant element are localized at high density at substitution positions and interstitial positions in the silicon single crystal. It has been experimentally found that when carbon and the dopant element are turned into a solid solution to the equilibrium concentration of the silicon single crystal or higher, the solid solubility of heavy metals (saturation solubility of transition metal) extremely increases. In other words, it appears that carbon and the dopant element made into a solid solution to the equilibrium concentration or higher increase the solubility of heavy metals, which results in significantly increased rate of trapping the heavy metals. This can also be attributed to the synergistic effect between the gettering effect due to carbon and the gettering effect due to the dopant element.

Here, since irradiation is performed with the cluster ions 16 in the present invention, higher gettering capability can be achieved as compared with the case of implanting monomer ions; moreover, recovery heat treatment can be omitted. Therefore, the semiconductor epitaxial wafers 100 and 200 achieving higher gettering capability can be produced, and the formation of white spot defects is expected to be suppressed in back-illuminated solid-state image sensing devices produced from the semiconductor epitaxial wafers 100 and 200 obtained by the production methods as compared to the conventional devices.

Note that “cluster ions” herein mean clusters formed by aggregation of a plurality of atoms or molecules, which are ionized by being positively or negatively charged. A cluster is a bulk aggregate having a plurality (typically 2 to 2000) of atoms or molecules bound together.

The inventors of the present invention consider that the mechanism of achieving high gettering capability by the irradiation with the cluster ions is as follows.

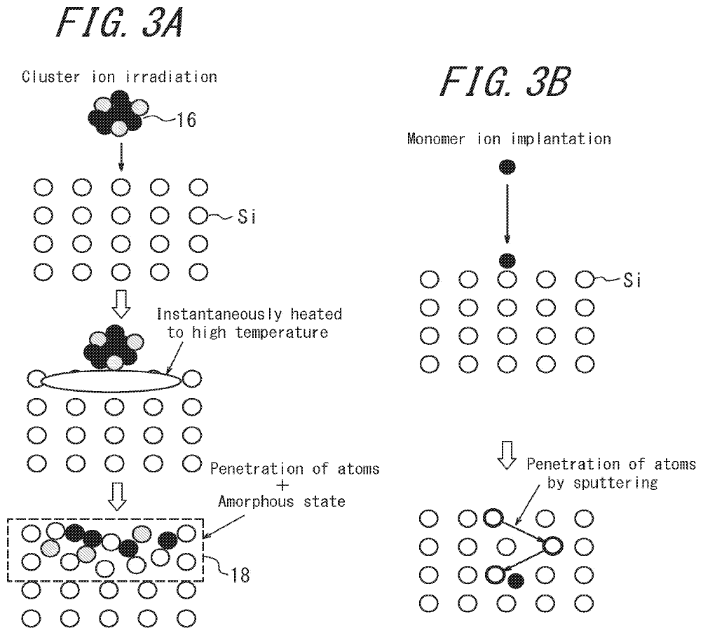

For example, when carbon monomer ions are implanted into a silicon wafer, the monomer ions sputter silicon atoms forming the silicon wafer to be implanted to a predetermined depth position in the silicon wafer, as shown in FIG. 3(B). The implantation depth depends on the kind of the constituent element of the implantation ions and the acceleration voltage of the ions. In this case, the concentration profile of carbon in the depth direction of the silicon wafer is relatively broad. When the implantation is performed simultaneously with a plurality of species of ions at the same energy, lighter elements are implanted more deeply, in other words, elements are implanted at different positions depending on their mass. Accordingly, the concentration profile of the implanted elements is broader in such a case. Further, also in cases where monomer ions of carbon are implanted and monomer ions of the dopant element are then implanted such that the peak positions of the concentration profile of the carbon and the dopant element overlap, since ion implantation requires a relatively high acceleration voltage, the concentration of the implanted dopant element is relatively broad as with the carbon concentration profile.

Monomer ions are typically implanted at an acceleration voltage of about 150 keV to 2000 keV. However, since the ions collide with silicon atoms with the energy, which results in the degradation of crystallinity of the surface portion of the silicon wafer, to which the monomer ions are implanted.

Accordingly, the crystallinity of an epitaxial layer to be grown later on the wafer surface is degraded. Further, the higher the acceleration voltage is, the more the crystallinity is degraded. Therefore, it is required to perform heat treatment for recovering the crystallinity having been degraded, at a high temperature for a long time after ion implantation (recovery heat treatment).

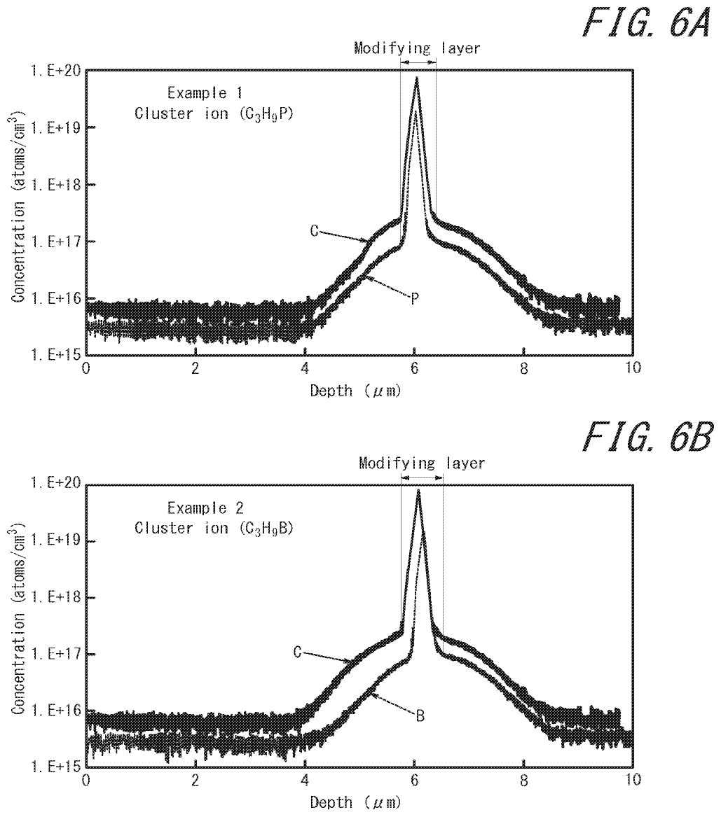

On the other hand, in cases where the silicon wafer is irradiated with cluster ions, for example, composed of carbon and a dopant element, for example, boron, as shown in FIG. 3(A), when the silicon wafer is irradiated with the cluster ions 16, the ions are instantaneously rendered to a high temperature state of about 1350° C. to 1400° C. due to the irradiation energy, thus melting silicon. After that, the silicon is rapidly cooled to form a solid solution of carbon and boron in the vicinity of the surface of the silicon wafer. Correspondingly, a “modifying layer” herein means a layer in which the constituent elements of the ions used for irradiation form a solid solution at crystal interstitial positions or substitution positions in the crystal lattice of the surface portion of the semiconductor wafer. The concentration profile of carbon and boron in the depth direction of the silicon wafer is sharper as compared with the case of monomer ions, although depending on the acceleration voltage and the cluster size of the cluster ions. The region where carbon and boron are localized (that is, the modifying layer) is a region having a thickness of approximately 500 nm or less (for example, about 50 nm to 400 nm). Note that the elements used for the irradiation in the form of cluster ions are thermally diffused to some extent in the course of formation of the epitaxial layer 20. Accordingly, in the concentration profile of carbon and boron after the formation of the epitaxial layer 20, broad diffusion regions are formed on both sides of the peaks indicating the localization of these elements. However, the thickness of the modifying layer does not change significantly (see FIGS. 6(A) and 6(B) described below). Consequently, carbon and boron are precipitated at a high concentration in a localized region. Since the modifying layer 18 is formed in the vicinity of the surface of the silicon wafer, further proximity gettering can be performed. This is considered to result in achievement of higher gettering capability than in the case of implanting monomer ions. Note that the irradiation can be performed simultaneously with a plurality of species of ions in the form of cluster ions unlike the case of implanting monomer ions.

In general, irradiation with cluster ions 16 is performed at an acceleration voltage of about 10 keV/Cluster to 100 keV/Cluster. However, since a cluster is an aggregate of a plurality of atoms or molecules, the ions can be implanted at reduced energy per one atom or one molecule. This results in less damage to the crystal of the silicon wafer. Further, cluster ion irradiation does not degrade the crystallinity of a silicon wafer 10 as compared with monomer-ion implantation also due to the above described implantation mechanism. Accordingly, after the first step, without performing recovery heat treatment on the silicon wafer 10, the silicon wafer 10 can be transferred into an epitaxial growth apparatus to be subjected to the second step (FIG. 1(C) and FIG. 2(D)).

The cluster ions 16 may include a variety of clusters depending on the binding mode, and can be generated, for example, by known methods described in the following documents. Methods of generating gas cluster beam are described in (1) JP 09-041138 A and (2) JP 04-354865 A. Methods of generating ion beam are described in (1) Junzo Ishikawa, “Charged particle beam engineering”, ISBN 978-4-339-00734-3 CORONA PUBLISHING, (2) The Institution of Electrical Engineers of Japan, “Electron/Ion Beam Engineering”, Ohmsha, ISBN 4-88686-217-9, and (3) “Cluster Ion Beam—Basic and Applications”, THE NIKKAN KOGYO SHIMBUN, ISBN 4-526-05765-7. In general, a Nielsen ion source or a Kaufman ion source is used for generating positively charged cluster ions, whereas a high current negative ion source using volume production is used for generating negatively charged cluster ions.

The conditions for irradiation with cluster ions will be described below. As described above, the elements used for the irradiation are carbon and a dopant element. Carbon atoms at a lattice site have a smaller covalent radius than silicon single crystals, so that a compression site is produced in the silicon crystal lattice, which results in high gettering capability for attracting impurities in the lattice. Further, carbon can sufficiently getter nickel and copper.

The dopant element used for irradiation is preferably one or more elements selected from the group consisting of boron, phosphorus, arsenic, and antimony. A solid solution is formed from the dopant element in addition to carbon, so that the gettering capability is further improved. The kinds of metals to be efficiently gettered depend on the kinds of the dopant elements forming the solid solution. For example, when the dopant element is boron, Fe, Cu, Cr, and the like can be gettered. Thus, a wider variety of metal contaminations can be handled.

The compounds to be ionized are not limited in particular. Ethane, methane, carbon dioxide (CO₂), dibenzyl (C₁₄H₁₄), cyclohexane (C₆H₁₂), and the like can be used as ionizable carbon source compounds, whereas diborane, decaborane (B₁₀H₁₄), and the like can be used as ionizalbe boron source compounds. For example, when a mixed gas of benzyl gas and decaborane gas is used as a material gas, a hydrogen compound cluster in which carbon, boron, and hydrogen are aggregated can be produced.

Further, examples of compounds containing both carbon and a dopant element, that can be ionized to be used as cluster ions include, but not limited to the compounds given below. Trimethylborane (C₃H₉B), triethylborane ((CH₃CH₂)₃B), carborane (C₂B₁₀H), boron carbide (CBₙ(1≤n≤4), and the like can be used as compounds containing both carbon and a dopant element. Phosphole (C₄H₅P), trimethylphosphine (C₃H₉P), triphenylphosphine (C₁₈H₁₅P), and the like can be used as compounds containing both carbon and phosphorus.

Further, the acceleration voltage and the cluster size of the cluster ions are controlled, thereby controlling the peak position of the concentration profile of the constituent elements in the depth direction of the modifying layer 18. “Cluster size” herein means the number of atoms or molecules constituting one cluster.

In the first step of this embodiment, in terms of achieving high gettering capability, the irradiation with the cluster ions 16 is performed such that the peak of the concentration profile of the constituent elements in the depth direction of the modifying layer 18 lies at a depth within 150 nm from the surface of the semiconductor wafer 10. Note that “the concentration profile of the constituent elements in the depth direction” herein means the profiles with respect to the concentrations of the respective single elements but not with respect to the total concentration of the constituent elements.

For a condition required to set the peak positions to the depth level, the acceleration voltage per one carbon atom is set to be higher than 0 keV/atom and 50 keV/atom or less, and preferably set to 40 keV/atom or less. Further, the acceleration voltage per one dopant element atom is set to be higher than 0 keV/atom and 50 keV/atom or less, and preferably set to 40 keV/atom or less. The cluster size is 2 to 100, preferably 60 or less, more preferably 50 or less.

In addition, for adjusting the acceleration voltage, two methods of (1) electrostatic field acceleration and (2) oscillating field acceleration are commonly used. Examples of the former method include a method in which a plurality of electrodes are arranged at regular intervals, and the same voltage is applied therebetween, thereby forming constant acceleration fields in the direction of the axes. Examples of the latter method include a linear acceleration (linac) method in which ions are transferred in a straight line and accelerated with high-frequency waves. The cluster size can be adjusted by controlling the pressure of gas ejected from a nozzle, the pressure of a vacuum vessel, the voltage applied to the filament in the ionization, and the like. The cluster size is determined by finding the cluster number distribution by mass spectrometry using the oscillating quadrupole field or by time-of-flight mass spectrometry, and finding the mean value of the cluster numbers.

The dose of the cluster ions can be adjusted by controlling the ion irradiation time. In this embodiment, in order to achieve the gettering function, the dose of carbon and the dopant element is preferably 1×10¹³ atoms/cm² to 1×10¹⁶ atoms/cm² each, more preferably 1×10¹⁴ atoms/cm² to 5×10¹⁵ atoms/cm² each. In a case of a carbon dose of less than 1×10¹³ atoms/cm², sufficient gettering capability would not be achieved, whereas a dose exceeding 1×10¹⁶ atoms/cm² would cause great damage to the epitaxial surface.

According to the present invention, as described above, it is not required to perform recovery heat treatment using a rapid heating/cooling apparatus or the like for RTA (Rapid Thermal Annealing), RTO (Rapid Thermal Oxidation), or the like, separate from the epitaxial apparatus. This is because the crystallinity of the silicon wafer 10 can be sufficiently recovered by hydrogen baking performed prior to epitaxial growth in an epitaxial apparatus for forming the epitaxial silicon layer 20 to be described below. For the conditions for hydrogen baking, the epitaxial growth apparatus has a hydrogen atmosphere inside. The silicon wafer 10 is placed in the furnace at a furnace temperature of 600° C. or more and 900° C. or less and heated to a temperature range of 1100° C. or more to 1200° C. or less at a heating rate of 1° C./s or higher to 15° C./s or lower, and the temperature is maintained for 30 s or more and 1 min or less. This hydrogen baking is performed essentially for removing natural oxide films formed on the wafer surface by a cleaning process prior to the epitaxial layer growth; however, the hydrogen baking under the above conditions can sufficiently recover the crystallinity of the silicon wafer 10.

Naturally, the recovery heat treatment may be performed using a heating apparatus separate from the epitaxial apparatus after the first step prior to the second step (FIG. 1(C) and FIG. 2(D)). This recovery heat treatment can be performed at 900° C. or more and 1200° C. or less for 10 s or more and 1 h or less. Here, the baking temperature is 900° C. or more and 1200° C. or less because when it is less than 900° C., the crystallinity recovery effect can hardly be achieved, whereas when it is more than 1200° C., slips would be formed due to the heat treatment at a high temperature and the heat load on the apparatus would be increased. Further, the heat treatment time is 10 s or more and 1 h or less because when it is less than 10 s, the recovery effect can hardly be achieved, whereas when it is more than 1 h, the productivity would drop and the heat load on the apparatus would be increased.

Such recovery heat treatment can be performed using, for example, a rapid heating/cooling apparatus for RTA or RTO, or a batch heating apparatus (vertical heat treatment apparatus or horizontal heat treatment apparatus). Since the former performs heat treatment using lamp radiation, its apparatus structure is not suitable for long time treatment, and is suitable for heat treatment for 15 min or less. On the other hand, the latter spends much time to rise the temperature to a predetermined temperature; however, it can simultaneously process a large number of wafers at once. Further, the latter performs resistance heating, which makes long time heat treatment possible. The heat treatment apparatus used can be suitably selected considering the irradiation conditions with respect to the cluster ions 16.

In the second step of this embodiment, the second epitaxial layer 20 formed on the modifying layer 18 may be an epitaxial silicon layer, and the concentration of the dopant element contained in the epitaxial layer is lower than the peak concentration of the dopant element forming a solid solution in the modifying layer 18. The second epitaxial layer can be formed, for example, under the following conditions. A source gas such as dichlorosilane or trichlorosilane can be introduced into a chamber using hydrogen as a carrier gas, so that the source material can be epitaxially grown on the semiconductor wafer 10 by CVD at a temperature in the range of approximately 1000° C. to 1200° C., although the growth temperature depends also on the source gas to be used. The dopant concentration of the second epitaxial layer can be adjusted by the amount of the dopant gas introduced during epitaxial growth. For the dopant gas, for example, in the case of boron doping, diborane gas (B₂H₆) can be used, while in the case of phosphorus doping, phosphine (PH₃) can be used. The thickness of the second epitaxial layer 20 is preferably in the range of 1 μm to 15 μm. When the thickness is less than 1 μm, the resistivity of the second epitaxial layer 20 would change due to out-diffusion of dopants from the semiconductor wafer 10, whereas a thickness exceeding 15 μm would affect the spectral sensitivity characteristics of the solid-state image sensing device. The second epitaxial layer 20 is used as a device layer for producing a back-illuminated solid-state image sensing device.

The combination of the conductivity types of the semiconductor wafer 10/modifying layer 18/second epitaxial layer 20 is not limited in particular, and any one of the p/n/p configuration, n/p/n configuration, p/p/p configuration, n/n/n configuration, n/n/p configuration, p/p/n configuration, p/n/n configuration, and n/p/p configuration can be employed.

The second embodiment shown in FIG. 2 also has a feature in that not the bulk semiconductor wafer 12 but the first epitaxial layer 14 is irradiated with cluster ions. The bulk semiconductor wafer has an oxygen concentration two orders of magnitude higher than that of the epitaxial layer. Accordingly, a larger amount of oxygen is diffused in the modifying layer formed in the bulk semiconductor wafer than in the modifying layer formed in the epitaxial layer, and the former modifying layer traps a large amount of oxygen. The trapped oxygen is released from the gettering site in a device fabrication process and diffused into an active region of the device to form point defects. This affects electrical characteristics of the device. Therefore, one important design condition in the device fabrication process is to irradiate an epitaxial layer having low solute oxygen concentration with cluster ions and to form a gettering layer in the epitaxial layer in which the effect of oxygen diffusion is almost negligible.

Here, in the process of producing a solid-state image sensing device, the bulk semiconductor wafer portion of the back side of the epitaxial wafer may be removed by polishing or etching. In such a case, the layer irradiated with cluster ions to form a solid solution containing the dopant at a high concentration can also serve as a polish stop layer or an etch stop layer in the thinning step in the device fabrication process. The peak position of the dopant element (traveled distance) can be controlled by changing the condition of the cluster-ion-irradiation energy (acceleration voltage). When irradiation is performed with cluster ions formed by ionizing a compound containing a plurality of elements, each element receives almost the same irradiation energy; therefore, if the peak position of each element is to be varied on purpose, the peak position of each element can be controlled, for example, by adjusting the size of each element to be used. Specifically, as the size of the element to be used is a larger, the concentration peak approaches the surface; on the other hand, as the element size is smaller, the concentration can be made to peak at a position deeper from the surface. Note that since the control range of the peak position by the adjustment of the element size is relatively small, instead of irradiation with cluster ions formed by ionizing a compound containing a plurality of elements, irradiations can be performed separately with cluster ions of each element at different irradiation energy, thereby the control range of the peak position of each element can be increased.

### (Semiconductor Epitaxial Wafer)

Next, the semiconductor epitaxial wafers 100 and 200 produced according to the above production methods will be described. A semiconductor epitaxial wafer 100 according to the first embodiment and a semiconductor epitaxial wafer 200 according to the second embodiment each has a semiconductor wafer 10; a modifying layer 18 formed from carbon and a dopant element contained as a solid solution in the semiconductor wafer 10, in a surface portion of the semiconductor wafer 10; and an epitaxial layer 20 on this modifying layer 18, as shown in FIG. 1(D) and FIG. 2(E). In the case of either wafer, characteristically, the half width W1 of the concentration profile of carbon in the modifying layer 18 and the half width W2 of the concentration profile of the dopant element therein are 100 nm or less, and the concentration of the dopant element in the epitaxial layer 20 is lower than the peak concentration of the dopant element in the modifying layer 18.

Correspondingly, according to the production method of the present invention, the elements constituting cluster ions can be precipitated at a high concentration in a localized region as compared with monomer-ion implantation, which results in the half widths W1 and W2 of 100 nm or less each. The lower limit thereof can be set to 10 nm. Note that the “concentration profile of carbon” and the “concentration profile of a dopant element” herein each mean a concentration distribution of each element in the depth direction, which is measured by secondary ion mass spectrometry (SIMS). Further, “the half width of the concentration profile” is a half width of the concentration profile of the certain elements measured by SIMS, with the epitaxial layer being thinned to 1 μm considering the measurement accuracy if the thickness of the epitaxial layer exceeds 1 μm.

Since in both the semiconductor epitaxial wafers 100 and 200, the peak concentration of the dopant element in the modifying layer 18 is higher than the concentration of the dopant element in the second epitaxial layer 20, impurity elements in the second epitaxial layer 20 can be gettered (gettered to the high concentration area) by the modifying layer 18 Further, since the first epitaxial layer 14 having low oxygen concentration and no defects is in the semiconductor epitaxial wafer 200, the diffusion of oxygen into the second epitaxial layer 20 can be suppressed. Accordingly, epitaxial defects caused by crystals, such as COPs can be prevented from being formed in the second epitaxial layer 20.

The dopant element forming a solid solution is preferably one or more elements selected from the group consisting of boron, phosphorus, arsenic, and antimony, as described above.

In terms of achieving higher gettering capability, for both of the semiconductor epitaxial wafers 100 and 200, the peak of the concentration profile of carbon and the dopant element in the modifying layer 18 lies at a depth within 150 nm from the surface of the semiconductor wafer 10. The peak concentration of the concentration profile of carbon is preferably 1×10¹⁵ atoms/cm³ or more, more preferably in the range of 1×10¹⁷ atoms/cm³ to 1×10²² atoms/cm³, sill more preferably in the range of 1×10¹⁹ atoms/cm³ to 1×10²¹ atoms/cm³. Further, when boron or phosphorus is used as the dopant element, the peak concentration of the concentration profile is preferably 1×10¹⁵ atoms/cm³ or more, more preferably in the range of 1×10¹⁷ atoms/cm³ to 1×10²² atoms/cm³, sill more preferably in the range of 1×10¹⁹ atoms/cm³ to 1×10²¹ atoms/cm³.

The thickness of the modifying layer 18 in the depth direction can be approximately in the range of 30 nm to 400 nm.

The concentration of the dopant element in the epitaxial layer 20 is preferably 1.0×10¹⁵ atoms/cm³ to 1.0×10²² atoms/cm³, more preferably, 1.0×10¹⁷ atoms/cm³ to 1.0×10²¹ atoms/cm³.

According to the semiconductor epitaxial wafers 100 and 200 of this embodiment, higher gettering capability can be achieved than conventional, which makes it possible to further suppress metal contamination.

### (Method of Producing Solid-State Image Sensing Device)

In a method of producing a solid-state image sensing device according to an embodiment of the present invention, a solid-state image sensing device can be formed on an epitaxial wafer produced according to the above producing methods or on the above epitaxial wafer, specifically, on the epitaxial layer 20 located in the surface portion of the semiconductor epitaxial wafers 100 and 200. For solid-state image sensing devices obtained by this producing method, the effects of metal contamination caused during the steps in the production process can be reduced and white spot defects can be sufficiently suppressed than conventional.

### EXAMPLES

### Reference Experimental Examples

First, in order to clarify the difference between cluster ion irradiation and monomer ion implantation, experiments were carried out as follows.

### Reference Example 1

An n-type silicon wafer (diameter: 300 mm, thickness: 725 μm, dopant: phosphorus, dopant concentration: 5×10¹⁴ atoms/cm³) obtained from a CZ single crystal silicon ingot was prepared. Next, trimethylphosphine (C₃H₉P) was ionized using a cluster ion generator (CLARIS produced by Nissin Ion Equipment Co., Ltd.) and the silicon wafer was irradiated with the ions under the conditions of carbon dose: 5.0×10¹⁴ atoms/cm², phosphorus dose: 1.7×10¹⁴ atoms/cm², acceleration voltage per one carbon atom: 12.8 keV/atom, and acceleration voltage per one phosphorus atom: 32 keV/atom.

### Reference Example 2

The same silicon wafer as Reference Example 1 was used and irradiated with ions under the same conditions as Reference Example 1 except that cluster ions were generated using trimethylborane (C₃H₉B) instead of trimethylphosphine as a material gas, the boron dose was 1.7×10¹⁴ atoms/cm², and the acceleration voltage per one boron atom was 14.5 kev/atom.

### Reference Example 3

The same silicon wafer as Reference Example 1 was used and implanted with monomer ions of carbon generated using CO₂ as a material gas, under the conditions of dose: 5.0×10¹⁴ atoms/cm² and acceleration voltage: 80 keV/atom, instead of being subjected to cluster ion irradiation. After that, monomer ions of phosphorus were generated using phosphine (PH₃) as a material gas and were implanted into the silicon wafer under the conditions of dose: 1.7×10¹⁴ atoms/cm² and acceleration voltage: 80 keV/atom.

### Reference Example 4

The same silicon wafer as Reference Example 1 was used and implanted with monomer ions of carbon generated using CO₂ as a material gas, under the conditions of dose: 5.0×10¹⁴ atoms/cm² and acceleration voltage: 80 keV/atom, instead of being subjected to cluster ion irradiation. After that, monomer ions of boron were generated using BF₂ as a material gas and were implanted into the silicon wafer under the conditions of dose: 1.7×10¹⁴ atoms/cm² and acceleration voltage: 80 keV/atom.

### (SIMS Results)

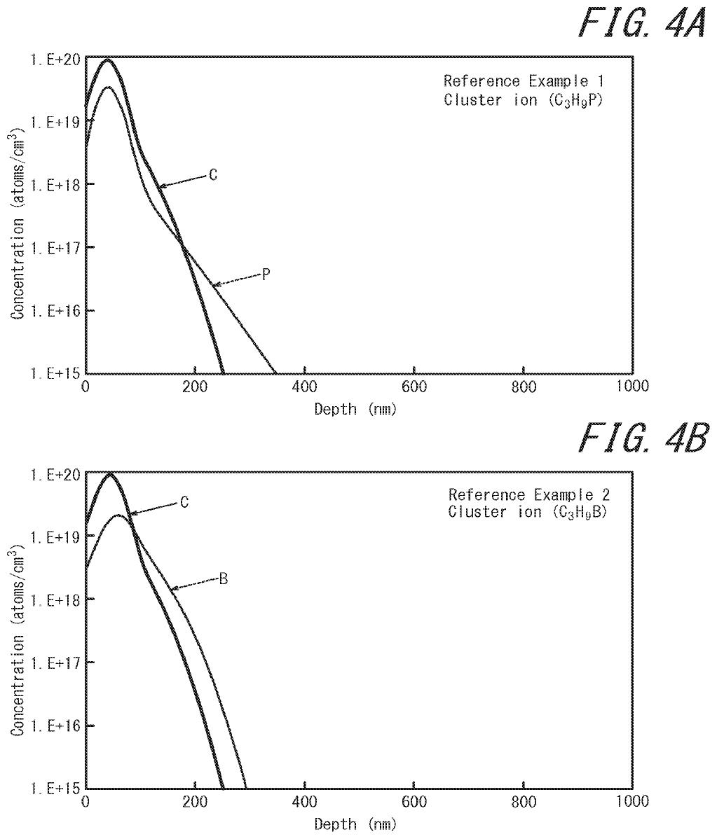

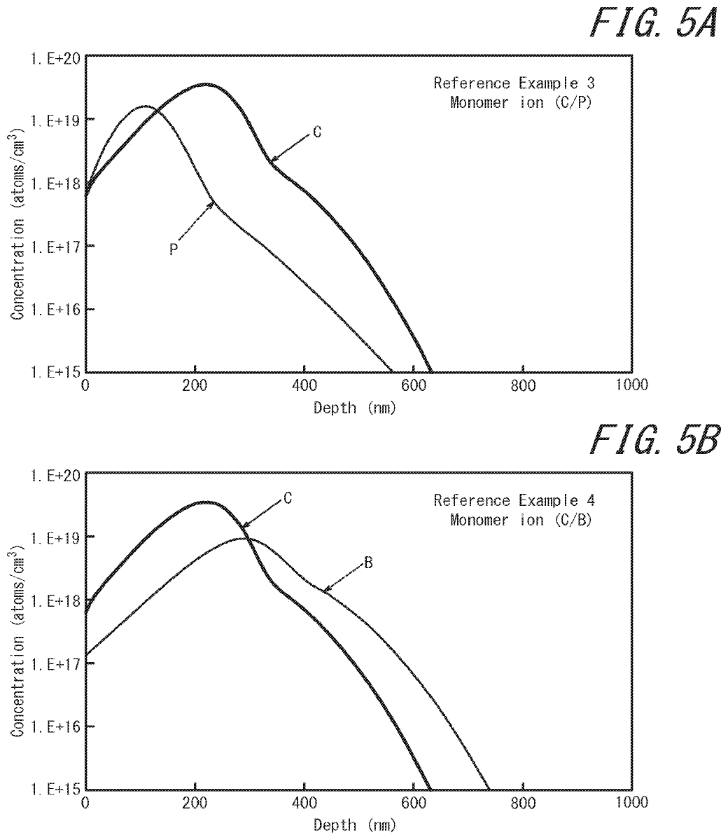

The samples prepared in Reference Examples 1 to 4 above were analyzed by secondary ion mass spectrometry (SIMS) to obtain the concentration profile of carbon and a dopant element, shown in FIGS. 4(A) and 4(B) and FIGS. 5(A) and 5(B). Note that the horizontal axis corresponds to the depth from the surface of the silicon wafer. As is clear from FIGS. 4(A) and 4(B) and FIGS. 5(A) and 5(B), in Reference Examples 1 and 2, in which cluster ion irradiation was performed, both the carbon concentration profile and the dopant element (phosphorus, boron) concentration profile are sharp; on the other hand, in Reference Examples 3 and 4, in which monomer ion implantation was performed, the carbon concentration profile and the dopant concentration profile are broad. Further, as compared with Reference Examples 3 and 4, the peak concentration of the concentration profile of carbon and the dopant element is higher and the peak position is closer to the surface of the semiconductor wafer in both Reference Examples 1 and 2. Therefore, the concentration profile of each element after forming the epitaxial layer is presumed to have the same tendency.

### Experimental Examples

### Example 1

An n-type silicon wafer (thickness: 725 μm, dopant: phosphorus, dopant concentration: 1×10¹⁵ atoms/cm³) obtained from a CZ single crystal silicon ingot was prepared. Next, cluster ions of trimethylphosphine (C₃H₉P) were generated using a cluster ion generator (CLARIS produced by Nissin Ion Equipment Co., Ltd.) and the silicon wafer was irradiated with the cluster ions under the irradiation conditions of carbon dose: 5.0×10¹⁴ atoms/cm², phosphorus dose: 1.7×10¹⁴ atoms/cm², acceleration voltage per one carbon atom: 12.8 keV/atom, and acceleration voltage per one phosphorus atom: 12.8 keV/atom. Subsequently, the silicon wafer was HF cleaned and then transferred into a single wafer processing epitaxial growth apparatus (produced by Applied Materials, Inc.) and subjected to hydrogen baking at 1120° C. for 30 s in the apparatus. After that, an epitaxial silicon layer (thickness: 6 μm, dopant: phosphorus, dopant concentration: 5×10¹⁵ atoms/cm³) was then epitaxially grown on the silicon wafer by CVD at 1000° C. to 1150° C. using hydrogen as a carrier gas, trichlorosilane as a source gas, and phosphine (PH₃) as a dopant gas thereby preparing an epitaxial silicon wafer of the present invention.

### Example 2

The same silicon wafer as Example 1 was used and irradiated with ions under the same conditions as Example 1 except that cluster ions were generated using trimethylborane (C₃H₉B) instead of trimethylphosphine as a material gas, the boron dose was 1.7×10¹⁴ atoms/cm², the acceleration voltage per one boron atom was 14.5 kev/atom, and an epitaxial layer (dopant: boron, dopant concentration: 5×10¹⁵ atoms/cm³) was grown; thereby preparing an epitaxial silicon wafer according to the present invention.

### Comparative Example 1

The same silicon wafer as Example 1 was used and implanted with monomer ions of carbon generated using CO₂ as a material gas, under the conditions of dose: 5.0×10¹⁴ atoms/cm² and acceleration voltage: 80 keV/atom, instead of being subjected to cluster ion irradiation. After that, an epitaxial silicon wafer of Comparative Example 1 was formed under the same conditions as Example 1 except that monomer ions of phosphorus were generated using phosphine (PH₃) as a material gas and were implanted into the silicon wafer under the conditions of dose: 1.7×10¹⁴ atoms/cm² and acceleration voltage: 80 keV/atom.

### Comparative Example 2

The same silicon wafer as Example 1 was used and implanted with monomer ions of carbon generated using CO₂ as a material gas, under the conditions of dose: 5.0×10¹⁴ atoms/cm² and acceleration voltage: 80 keV/atom, instead of being subjected to cluster ion irradiation. After that, an epitaxial silicon wafer of Comparative Example 2 was formed under the same conditions as Example 1 except that monomer ions of boron were generated using BF2 as a material gas and were implanted into the silicon wafer under the conditions of dose: 1.7×10¹⁴ atoms/cm² and acceleration voltage: 80 keV/atom.

### Comparative Example 3

An epitaxial silicon wafer of Comparative Example 3 was formed under the same conditions as Example 1 except that the same silicon wafer as Example 1 was used and implanted with monomer ions of carbon generated using CO₂ as a material gas, under the conditions of dose: 5.0×10¹⁴ atoms/cm² and acceleration voltage: 80 keV/atom, instead of being subjected to cluster ion irradiation.

### (Evaluation Method and Evaluation Result)

### (1) SIMS

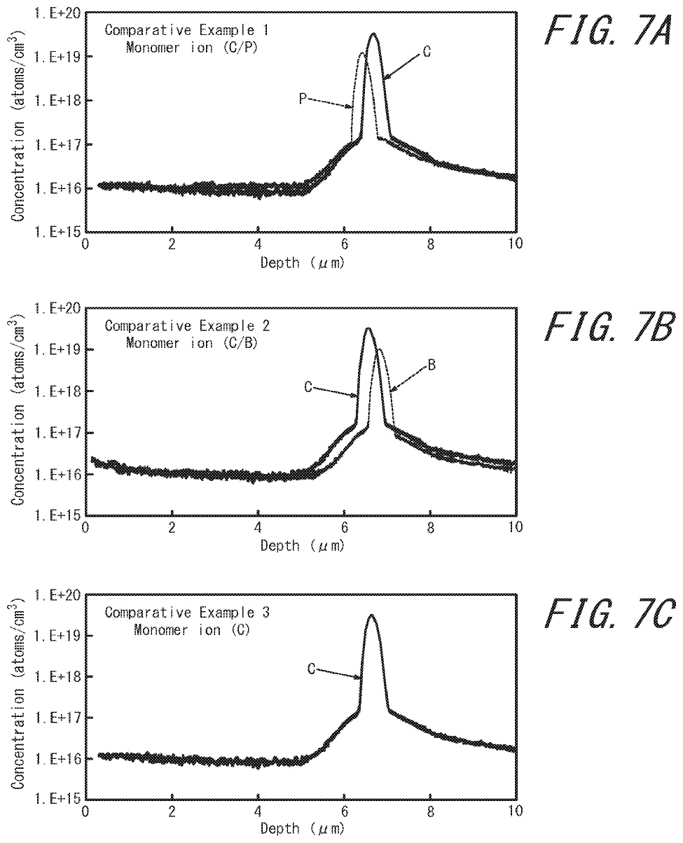

The prepared samples were each analyzed by SIMS to obtain the concentration profile of carbon and a dopant element, shown in FIGS. 6(A) and 6(B) and FIGS. 7(A), 7(B), and 7(C). Note that FIG. 7(C) shows the concentration profile of only carbon, since no dopant element is implanted. Note that the horizontal axis corresponds to the depth from the surface of the epitaxial layer. Each sample prepared was analyzed by SIMS after thinning the epitaxial layer to 1 μm. Thus obtained half width, peak concentration, and peak position (peak depth from the surface of the silicon wafer with the epitaxial layer having been removed) of the concentration profile of carbon and the dopant element were classified according to the following criteria and shown in Table 1.

### Half Width

++: 100 nm or less
+: more than 100 nm and 125 nm or less
−: more than 125 nm

### Peak Position

++: 125 nm or less
+: more than 125 nm 150 nm or less
−: more than 150 nm

### Peak Concentration

++: 5.0×10¹⁹ atoms/cm³ or more
+: 2.0×10¹⁹ atoms/cm³ or more and less than 5.0×10¹⁹ atoms/cm³
−: less than 2.0×10¹⁹ atoms/cm³

### (2) Gettering Capability Evaluation

The surface of the epitaxial layer in each sample prepared was contaminated on purpose by the spin coat contamination process using a Ni contaminating agent (1.0×10¹⁴/cm²) and a Cu contaminating agent (1.0×10¹⁴/cm²) and was then subjected to diffusion heat treatment at 1000° C. for one hour. After that the gettering capability was evaluated by performing SIMS. The amount of Ni and Cu gettered (the integral of the SIMS profile) was classified into the following categories to be used as criteria. The results of the evaluation are shown in Table 1.

++: 7.5×10¹³ atoms/cm² or more and less than 1×10¹⁴ atoms/cm²
+: 5.0×10¹³ atoms/cm² or more and less than 7.5×10¹³ atoms/cm²
−: less than 5.0×10¹³ atoms/cm²

TABLE 1

| | | | Epitaxial silicon wafer | | | | |
|---|---|---|---|---|---|---|---|
| | Irradiation/implantation | | | | | Gettering | |
| | condition | | | Peak | Peak | Capability | |
| | Monomer/Cluster | Ion species | Half width | position | concentration | Ni | Cu |
| Example 1 | Cluster ion | C₃H₉P | C: ++ | C: ++ | C: ++ | ++ | ++ |
| | | | P: ++ | P: ++ | P: + | | |
| Comparative | Monomer ion | C/P | C: − | C: − | C: + | − | − |
| Example 1 | | | P: + | P: + | P: − | | |
| Example 2 | Cluster ion | C₃H₉B | C: ++ | C: ++ | C: ++ | ++ | ++ |
| | | | B: ++ | B: ++ | B: + | | |
| Comparative | Monomer ion | C/B | C: − | C: − | C: + | − | − |
| Example 2 | | | B: − | B: − | B: − | | |
| Comparative | Monomer ion | C | C: − | C: − | C: + | − | − |
| Example 3 | | | | | | | |

### (Discussion on Evaluation Results)

Comparing FIGS. 6(A) and 6(B) with FIGS. 7(A), 7(B), and 7(C), a modifying layer is found to be formed, which is a solid solution of carbon and the dopant element localized at high concentration, by cluster ion irradiation in Examples 1 and 2. Further, Table 1 shows that the half width of the concentration profile of carbon and the dopant element was 100 nm or less in both Examples 1 and 2, which resulted in more excellent gettering effects on both Ni and Cu than in Comparative Examples 1 to 3.

As is clear from FIGS. 6(A) and 6(B) and FIGS. 7(A) and 7(B), in each case, a peak concentration higher than the dopant (phosphorus in Example 1 and Comparative Example 1, boron in Example 2 and Comparative Example 2) concentration of the epitaxial layer was observed in the modifying layer.

### INDUSTRIAL APPLICABILITY

According to the present invention, higher gettering capability is achieved, so that a semiconductor epitaxial wafer which can suppress metal contamination can be obtained and a high quality solid-state image sensing device can be formed from the semiconductor epitaxial wafer.

### REFERENCE SIGNS LIST

10: Semiconductor wafer
10A: Surface portion of semiconductor wafer
12: Bulk semiconductor wafer
14: First epitaxial layer
16: Cluster ions
18: Modifying layer
20: (Second) epitaxial layer
100: Semiconductor epitaxial wafer
200: Semiconductor epitaxial wafer

1. A method of producing a semiconductor epitaxial wafer, comprising:
a first step of irradiating a surface portion of a semiconductor wafer with cluster ions thereby forming a modifying layer formed from carbon and a dopant element contained as a solid solution that are constituent elements of the cluster ions, in the surface portion of the semiconductor wafer; and
a second step of forming an epitaxial layer on the modifying layer of the semiconductor wafer, the epitaxial layer having a dopant element concentration lower than the peak concentration of the dopant element in the modifying layer.

2. The method of producing a semiconductor epitaxial wafer, according to claim 1, wherein the cluster ions are formed by ionizing a compound containing both the carbon and the dopant element.

3. The method of producing a semiconductor epitaxial wafer, according to claim 1 or 2, wherein the dopant element is one or more elements selected from the group consisting of boron, phosphorus, arsenic, and antimony.

4. The method of producing a semiconductor epitaxial wafer, according to any one of claims 1 to 3, wherein the semiconductor wafer is a silicon wafer.

5. The method of producing a semiconductor epitaxial wafer, according to any one of claims 1 to 3, wherein the semiconductor wafer is an epitaxial silicon wafer in which an epitaxial silicon layer is formed on a surface of a silicon wafer, and the modifying layer is formed in the surface portion of the epitaxial silicon layer in the first step.

6. The method of producing a semiconductor epitaxial wafer, according to any one of claims 1 to 5, further comprising, after the first step and before the second step, a step of performing heat treatment for recovering the crystallinity on the semiconductor wafer.

7. A semiconductor epitaxial wafer, comprising:
a semiconductor wafer; a modifying layer formed from carbon and a dopant element contained as a solid solution in the semiconductor wafer, the modifying layer being formed in a surface portion of the semiconductor wafer; and an epitaxial layer on the modifying layer,
wherein the half width of the concentration profile of the carbon in the modifying layer and the half width of the concentration profile of the dopant element therein are 100 nm or less, and
the concentration of the dopant element in the epitaxial layer is lower than the peak concentration of the dopant element in the modifying layer.

8. The semiconductor epitaxial wafer according to claim 7, wherein the dopant element is one or more elements selected from the group consisting of boron, phosphorus, arsenic, and antimony.

9. The semiconductor epitaxial wafer according to claim 7 or 8, wherein the semiconductor wafer is a silicon wafer.

10. The semiconductor epitaxial wafer according to claim 7 or 8, wherein the semiconductor wafer is an epitaxial silicon wafer in which an epitaxial silicon layer is formed on a surface of a silicon wafer, and the modifying layer is located in the surface portion of the epitaxial silicon layer.

11. The semiconductor epitaxial wafer according to any one of claims 7 to 10, wherein the peak of the concentration profile of the carbon and the dopant element in the modifying layer lies at a depth within 150 nm from the surface of the semiconductor wafer.

12. The semiconductor epitaxial wafer according to any one of claims 7 to 11, wherein the peak concentration of the concentration profile of the carbon in the modifying layer is 1×10¹⁵ atoms/cm³ or more.

13. The semiconductor epitaxial wafer according to any one of claims 7 to 12, wherein the peak concentration of the concentration profile of the dopant element in the modifying layer is 1×10¹⁵ atoms/cm³ or more.

14. A method of producing a solid-state image sensing device, wherein a solid-state image sensing device is formed in an epitaxial layer located in the surface portion of the epitaxial wafer fabricated by the production method according to any one of claims 1 to 6 or of the epitaxial wafer according to any one of claims 7 to 13.
